(19) United States
(12) Patent Application Publication
(10) Pub. No.: US 2008/0265403 A1
(43) Pub. Date: Oct. 30, 2008

(54) Hybrid Metal Matrix Composite Packages with High Thermal Conductivity Inserts

(75) Inventors: James Allen Cornie, Cambridge, MA (US); Stephen Shawn Cornie, Watertown, MA (US); Yuejian Chen, Clifton Park, NY (US); Larry Ballard, Watertown, MA (US)

Correspondence Address: RAUSCHENBACH PATENT LAW GROUP, LLC, P.O. BOX 387, BEDFORD, MA, 01730, US

(73) Assignee: METAL MATRIX CAST COMPOSITES, LLC, Waltham, MA (US)

(21) Appl. No.: 11/306,343

(22) Filed: Dec. 23, 2005

Related U.S. Application Data
(60) Provisional application No. 60/639,974, filed on Dec. 29, 2004.

(51) Int. Cl. H01L 23/34

(52) U.S. Cl. 257/706

(57) ABSTRACT

A hybrid package for heat sinking a device is formed of a graphitic material that defines a plurality of cavities for cast-in-rivets and that defines at least one cavity for a cast-in-rivet via. The graphitic material is pressure infiltrated with a molten metal alloy so as to form a composite material with a plurality of cast-in rivets that increases at least one of the through-plane conductivity and the strength of the hybrid package and that forms at least one cast-in-rivet that increases an in-plane thermal conductivity of the hybrid package.

### RELATED APPLICATION SECTION

This application claims priority to U.S. Provisional Patent Application Ser. No. 60/639,974, filed Dec. 29, 2004, and entitled “Hybrid Metal Matrix Composite Structures with Highly Conductive Thermal Pyrolytic Graphite Inserts.” The entire application of U.S. Provisional Patent Application Ser. No. 60/639,974 is incorporated herein by reference.

### FEDERAL RESEARCH STATEMENT

This invention was made with Government support under Grant Numbers N00178-03-C-1088, DASG-60-03-P-0162, FA 8650-04-M-5220, N00164-04-C-6041, N00024-05-C-4103, and N00178-05-C-3048 awarded by the U.S. Naval Sea Systems Command. The Government has certain rights in this invention.

### BACKGROUND OF THE INVENTION

The section headings used herein are for organizational purposes only and should not be construed as limiting the subject matter described in the present application.

Modern electronic devices and systems, such as cellular phones, radar systems, high power RF and microwave devices, and imaging systems are being manufactured with continually increasing capabilities and operating speeds. In addition, modern electronic devices and systems are being manufactured with continually increasing semiconductor die sizes and device densities in order to provide more functions and higher performance in smaller system dimensions.

Such electronic devices must dissipate large amounts of heat during normal operation. For example, wide band gap semiconductors, such as GaN and SiC operate at relatively high temperatures and can generate heat energy greater than 100 W/cm². Such devices generally require heat spreader/heat sinks to dissipate the heat energy. It is expected that the heat generated by future electronic devices will continue to increase.

Electronic devices can be directly attached to a heat spreader/heat sink or can be encased in a ceramic package that protects the device and provides electrical connections. Common ceramic packages include silicon carbide, aluminum oxide, aluminum nitride, gallium nitride, gallium arsenide, and beryllium oxide. The coefficient of thermal expansion (CTE) of the electronic devices and the ceramic packages are usually matched as closely as possible to avoid thermal cycling induced mechanical stress failures. Thermal cycling arises during power up and power down cycles in combination with resistive heating caused by current flowing in the device.

In addition, many other industries require materials that CTE match other materials. Some of these materials must also be lightweight, stiff, and capable of damping undesirable vibrations. For example, materials used for precise motion control often must have a particular CTE. Also, some materials used in the optics industry for mirrors, optical benches, metering devices, as well as other kinds of mechanical hardware, must also have a particular CTE.

### BRIEF DESCRIPTION OF THE DRAWINGS

The invention, in accordance with preferred and exemplary embodiments, together with further advantages thereof, is more particularly described in the following detailed description, taken in conjunction with the accompanying drawings. The drawings are not necessarily to scale, emphasis instead generally being placed upon illustrating principles of the invention.

FIG. 1 illustrates a table that presents data for thermal conductivity, thermal expansion coefficient, and density for several known materials used for CTE matching and high thermal conductivity device packaging.

FIG. 2 illustrates a schematic view of a hybrid package that includes cast-in-rivets and cast-in-rivet vias according to the present invention for mounting a device requiring heat sinking.

FIG. 3 illustrates a schematic view of a hybrid package formed of a skin composite material that encapsulates a core composite material.

FIG. 4 illustrates a plot of calculated in-plane thermal conductivity, through-plane thermal conductivity, and CTE as a function of volume fraction of TPG™.

FIG. 5 illustrates a schematic view of another embodiment of a hybrid package formed of a skin composite material that encapsulates a core composite material that includes a CTE matching composite material insert positioned beneath the device requiring heat sinking.

FIG. 6 shows a schematic diagram of a core composite material during pressure infiltration that illustrates a method of positioning a core composite material in a hybrid package according to the present invention.

FIG. 7A is a schematic diagram illustrating the measurement of steady state thermal conductivity of a hybrid package fabricated according to the present invention.

FIG. 7B presents a table of data for thermal flux conducted through the hybrid package.

FIG. 8 presents a table of CTE data and overall thermal conductivity data for five different cast-in-rivet via materials.

### DETAILED DESCRIPTION

While the present teachings are described in conjunction with various embodiments and examples, it is not intended that the present teachings be limited to such embodiments. On the contrary, the present teachings encompass various alternatives, modifications and equivalents, as will be appreciated by those of skill in the art.

It should be understood that the individual steps of the methods of the present invention might be performed in any order and/or simultaneously as long as the invention remains operable. Furthermore, it should be understood that the apparatus of the present invention could include any number or all of the described embodiments as long as the invention remains operable.

Known heat sinks are commonly fabricated from metals, such as copper, molybdenum, tungsten and aluminum. A metal heat sink is often plated with nickel prior to attachment to a ceramic package at an elevated temperature. Alternatively, silver-filled adhesives, or other conductive metal powder-filled adhesives, are sometimes used for bonding.

Choosing a metal or other material for a heat sink often involves a trade-off between desirable and undesirable properties. Some metals, such as aluminum and copper have high thermal conductivity, but have Coefficient of Thermal Expansion values (CTEs) that are several times greater than that of the ceramic package or semiconductor die. During power cycling of an electronic component, the temperature of the component and the attached heat sink fluctuate significantly. Consequently, such metals cause mechanical stress to the heat sink bonding material during power cycling. The differential expansion of the heat sink relative to the ceramic package or semiconductor die can cause failure of the bond material or cracking of the package or die.

Other metals, such as tungsten and molybdenum, have relatively small CTEs. Although such metals can permit a reliable bond, they have lower thermal conductivity than aluminum or copper substrates and they are difficult to electroplate. Furthermore, tungsten and molybdenum are undesirable for applications that require relatively light weight.

Composites of copper and tungsten or of copper and molybdenum have certain advantages over elemental materials. These composites can be made by various methods of powder metallurgy, such as, for example, infiltrating copper into a sintered body of tungsten or molybdenum, or sintering a mixed powder of the two metals. However, sintered ingots of tungsten and molybdenum are difficult to roll into elongated plates. Alternatively, metal layers can be joined by cladding or lamination. Cladded and laminated products, however, require precise machining, which is labor-intensive, error-prone, and expensive.

Some heat sinks combine a sintered ceramic with a metal matrix. The fabrication process involves the formation of a ceramic preform, which can be made by, for example, sintering silicon carbide powder. The ceramic preform microstructure typically has a predetermined void volume fraction that is subsequently filled with a molten metal, which is typically aluminum. The thermal conductivity of aluminum ceramic heat sinks can be improved by using copper-based inserts. Such heat sinks, however, can be difficult to manufacture and have a relatively narrow range of possible CTEs.

Other heat sinks are formed of metal matrix composites that include infiltrated inorganic fiber material. Infiltration of fibers is sometimes difficult because of problems with fiber wetting and non-uniform fiber distribution. In addition, molten metal infiltration of fibers under pressure can displace the fibers due to the fiber breakthrough pressure threshold. Furthermore, it is often difficult to control fiber volume fraction, and thus to obtain desired properties of the composite. These factors have limited the use of metal matrix fiber composites as heat sinks.

Metal matrix composite (“MMC”) materials that include discontinuous high-modulus graphite fibers that are randomly arranged in-plane at desired volume fractions have significant advantages over many known material used for heat spreaders and heat sinks. Such composites are disclosed in U.S. patent application Ser. No. 10/379,044, filed Mar. 4, 2003, entitled “Discontinuous Carbon Fiber Reinforced Metal Matrix Composite,” which is assigned to the present assignee. The entire application of U.S. patent application Ser. No. 11/163,486 is incorporated herein by reference. One advantage is that MMC materials can be used to fabricate heat sink base plates with relatively high thermal conductivity and with CTEs that match the CTEs of common ceramic package materials.

One method of manufacturing a MMC with randomly distributed graphite fibers is disclosed in U.S. patent application Ser. No. 10/379,044. This method includes mixing dry PEG binder material with dry-milled graphite fibers having an average length of about 300 microns. The mix is then poured into a mold, pressed, and heated to liquefy the binder. The mix is then chilled to set the binder prior to removal from the die.

The resulting preform is inserted into a pressure infiltration casting mold vessel for metal infiltration and solidification. This process is relatively simple and inexpensive. The fiber distribution obtained with this process is relatively non-uniform and may result in a standard deviation on order of about 2 ppm at a volume fraction that results in a CTE of 7 ppm/K. Thus, this method may not be suitable for applications requiring particularly close CTE matching to a material. In addition, non-uniform and largely unpredictable fiber distribution may result in warping of plates machined from the casting while processing through the various machining steps or through soldering operations.

Another method of manufacturing a MMC with randomly distributed graphite fibers is disclosed in U.S. Pat. No. 5,437,921. This method includes dispersing milled fibers in an aqueous slurry, which is then poured into a filter vessel. The aqueous slurry is formed into a filter cake under vacuum and then pressed to a desired volume fraction. The filter cake is then dried and pressed to the desired volume fraction. This process, and other processes that use milled fibers, tends to develop preferred fiber orientations when the fibers experience flow alignment. Flow alignment occurs when dry milled fibers are poured into a mold where they exhibit aligned flow that cannot be re-randomized. Also, this process, and other processes that use milled fibers, is prone to forming localized non-uniform distributions due to localized flow alignment of milled fibers during pouring and vacuum filtration steps. Other problems with this process include a variation of packing density with thickness and significant variations of CTE. For example, the standard deviation can be 1.25 ppm/K at an average level of CTE equal to 7 ppm/K.

Another known method of manufacturing a MMC with randomly distributed graphite fibers includes incorporating chopped CKD graphite fibers with an average chop length of 25 mm into a paper product. This method is used commercially by Technical Fibre Products of Cumbria in the United Kingdom. The method requires adding a co-polyester fiber, which serves as a binder. The paper product is laid out into a die and then heated to soften the binder fiber. The preform is then pressed to the desired volume fraction. Each ply is rotated through a sequence of orientations to produce a substantially planar isotropic preform. This process results in a lower standard deviation that is about 0.9 ppm/K. However, the process is relatively expensive and the through-plane thermal conductivity is relatively low. In addition, the polyester binder is typically difficult to remove and has relatively a high char yield during the outgasing and preheating operation.

There currently is a significant need in the electronic thermal management and packaging industry to fabricate MMC base plates with high thermal conductivity in various directions in order to achieve both heat spreading and through-plane thermal conductivity. Heat spreading requires high in-plane thermal conductivity. Heat sinking requires high “z” or through-plane thermal conductivity. The term “in-plane” as used herein refers to the plane parallel to a bonded surface of a heat sink. The term “through-plane” as used herein refers to a direction that is orthogonal to an in-plane surface.

A new method of manufacturing a MMC is disclosed in U.S. patent application Ser. No. 11/163,486, filed Oct. 20, 2005, entitled “Spray Deposition Apparatus and Methods for Metal Matrix Composites,” which is assigned to the present assignee. The entire application of U.S. patent application Ser. No. 11/163,486 is incorporated herein by reference. This method forms MMC materials with discontinuous high modulus graphite fibers that are arranged in-plane with a majority of fibers oriented substantially off the basal plane at the desired volume fraction. This method does not suffer from many of the problems associated with known methods of manufacturing MMC devices. In addition, this method can produce MMC devices with predetermined thermal expansion properties that are controllably matched to those of a wide range of materials that are commonly used as electronic substrates. Furthermore, this method can produce MMC devices that have nearly isotropic thermal conductivity properties that provide high thermal conductivity for both heat spreading and heat sinking.

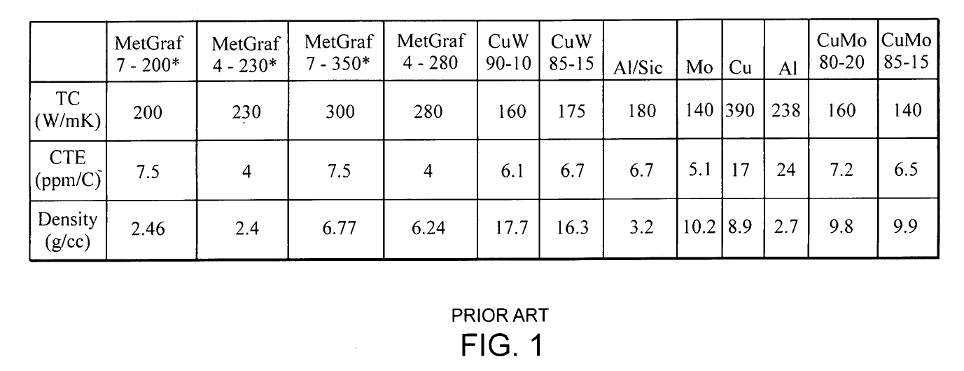

FIG. 1 illustrates a table 100 that presents data for thermal conductivity (“TC”), thermal expansion coefficient (CTE), and density of several known materials used for CTE matching and high thermal conductivity device packaging. The table 100 presents data for MetGraf™ composite material, CuW, Al/SiC, Mo, Cu, Al, and CuMo. The term “MetGraf™” that appears in table 100 is a trade name for a metal matrix composite material commercially available from Metal Matrix Cast Composites of Waltham, Mass., the assignee of the present application.

MetGraf™ is a metal matrix composite material that includes a matrix of random discontinuous high-modulus graphite fibers that is pressure infiltrated with molten Al or Cu alloy. MetGraf™ preform material can have a volume fraction that is chosen to provide precise CTE matching to a particular material. For example, MetGraf™ 4 and 7 refer to discontinuously reinforced Al and Cu alloys in which the matrix alloy is pressure infiltrated into a compressed preform to produce an in-plane CTE of 4 or 7. MetGraf™ preforms can be produced using one of the processes described in U.S. patent application Ser. No. 11/163,486 described herein.

MetGraf™ composites are often manufactured from milled graphite fibers having a length of about 300 microns. Fibers available from Cytec Industries Inc. in West Paterson, N.J., under the trade name DKD or DKAx, or other similar discontinuous fibers, can be used to form MetGraf™. MetGraf™ can be formed by arranging these fibers into a sheet by one of the methods disclosed in U.S. patent application Ser. No. 11/163,486. The sheets are then compressed to a volume fraction that is chosen to match a particular CTE after infiltration with Al or Cu alloy as described in U.S. Pat. No. 6,148,899 and U.S. patent application Ser. No. 11/163,486. The particular CTE is determined by the degree of compression in the graphite preform, which results in a particular volume fraction in the final infiltrated composite. Typically, such materials have a CTE of 4 ppm/K or 7 ppm/K.

The data in table 100 indicates that various types of MetGraf™ materials have desirable properties, relatively high thermal conductivity, relatively low density, and can be CTE matched to devices requiring heat sinking. MetGraf™ composite materials are useful for removing thermal energies flux densities under 100 W/mK.

A material known in the industry as SpreaderShield 30-500 has a high in-plane thermal conductivity that is in the range of 500-530 W/mK. SpreaderShield 30-500 is a relatively inexpensive natural graphite product that is available from GrafTech International Ltd. in Wilmington, Del. However, like all crystalline graphitic materials, the thermal conductivity in the “through-plane” direction is relatively low, in the range of about 10-20 W/mK.

A material known in the industry as thermal pyrolytic graphite (TPG™), which is available from General Electric Advanced Ceramics in Cleveland, Ohio, includes crystalline graphite plates. Thermal pyrolytic graphite has relatively high in-plane (X-Y) thermal conductivity of about 1,700 W/mK. However, TPG™ has a very low through-plane thermal conductivity of about 20 W/mK because it is difficult to dissipate or “sink” the heat into the graphite planes where the graphite structure can quickly remove the heat in-plane with very high thermal conductivities. Thermal pyrolytic graphite is useful as a thermal heat sink because it will spread heat along the 1700 W/mK planes and can also CTE match to some semiconductor devices.

Aluminum can be embedded into TPG™ using hot isostatic press bonding to produce sheets and plates with thin Al skin and a TPG™ core. Such material is known in the industry as TC-1050. One problem with TC-1050 is that the material is prone to delamination during thermal cycling because the TPG™ core has a CTE of 0 to −1 ppm/K and the cladding Al alloy has a CTE of 24 ppm/K. Delamination of the interface between the Al skin and the TPG™ core is undesirable because it results in a loss of heat transfer capacity. U.S. Pat. No. 5,296,310 to K Technology Corporation in Fort Washington, Pa. describes a clad material known in the industry as Annealed Pyrolytic Graphite (APG™) that has similar properties to GE's TC-1050 and the same delamination problem. Both GE's TC-1050 and K Technology Corporation's APG™ material are physically uncoupled to the skin material so the TPG™ and APG™ core material is free to move relative to the skin. In contrast, hybrid packages according to many embodiments of the present invention have a composite material skin that is coupled to the composite material core, which integrates the core composite material into the package thereby making the package more robust and more resistant to delamination.

Yet another material developed by Ceramic Processing Systems of Chartley, Mass. embeds TPG™ in an AlSiC composite material using a pressure infiltration casting process. The resulting material has a thermal conductivity that is about 1,000 W/mK (depending on the thickness of the Al/SiC cladding) and a CTE that is about 9 ppm/K. This material is only marginally acceptable for a heat sink. In addition, this material is brittle and prone to delamination, which results in heat loss.

Clad insert structures known in the art have relatively high thermal conductivities, but lack structural robustness and are also prone to delamination, which results in loss of heat transfer capacity. In addition, these materials lack the ability to CTE match to the substrate. K Technology Corporation in Fort Washington, Pa. proposed a method of increasing the through-plane thermal conductivity by heat sinking vias from a surface mounted chip into the highly conducive graphitic planes.

Currently there exists a need for a package that exhibits enhanced structural strength, high through-plane thermal conductivity, and that has a CTE that matches the CTE of common electronic devices and ceramic package materials. The present invention features a composite material structure that provides both high through-plane thermal conductivity and high structural strength. The composite material can also be engineered to CTE match common ceramic package materials. Unlike many other high performance composite materials, the composite material of the present invention does not exhibit delamination.

One aspect of the present invention is that it has been discovered that certain materials, such as highly-oriented pyrolytic graphite (“HOPG”) materials in foil or sheet form, can be machined with cavities for rivets and rivet-vias which, after infiltration with molten Al or Cu alloys, serve to produce a cladding material with cast-in rivets that add significant strength and robustness to a package assembly. Such HOPG materials include TPG™ graphite sheets that are commercially available from GE Advanced Ceramics of Cleveland, Ohio or GRAFOIL® flexible graphite foil that is commercially available from GrafTech International Ltd. of Wilmington, Del.

In some embodiments of the present invention, high conductivity HOPG plates with pre-machined cavities for rivets and rivet-vias are encapsulated in discontinuous graphite fiber preforms prior to infiltration. A surface skin is produced after infiltration that can be engineered to have a CTE that matches the CTE of many electronic devices and packages. In some embodiments of the present invention, rivet-vias are used to enhance through-plane thermal conductivity in order to improve the transfer of heat into the highly conductive graphite planes. In some embodiment of the present invention, rivet-vias are used to modify local expansion coefficients to improve the CTE match to an electronic package or semiconductor device. In other embodiments, rivet-vias are used to both enhance through-plane conductivity and to modify local expansion coefficients to improve CTE matching.

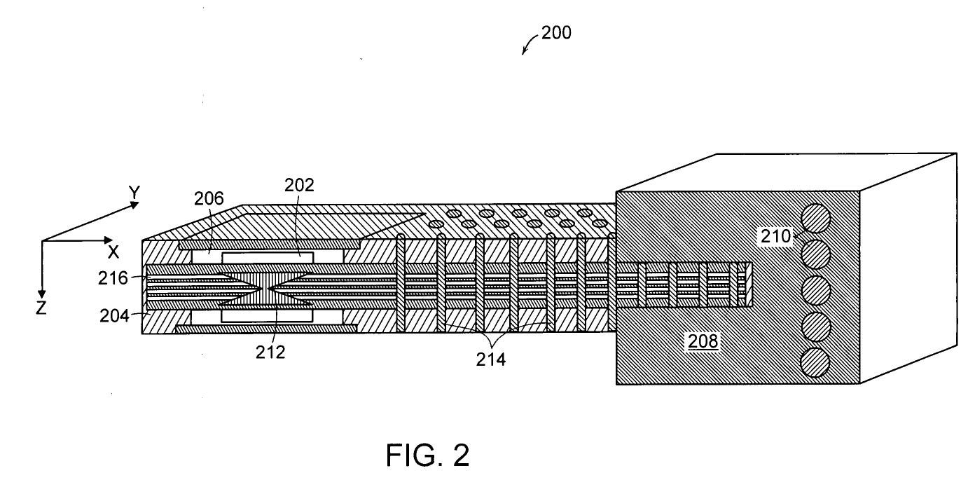

FIG. 2 illustrates a schematic view of a hybrid package 200 that includes cast-in-rivets and cast-in-rivet vias according to the present invention for mounting a device 202 requiring heat sinking. The hybrid package 200 includes a cold-plate body 204 for mounting the device 202. In the embodiment shown in FIG. 2, the hybrid package 200 includes a recessed area 206 for mounting the device 202. In the examples presented herein, the device 202 is a semiconductor device, such as an amplifier chip. However, one skilled in the art will appreciate that the methods and apparatus of the present invention can be used with any type of device that requires heat sinking. For example, the device requiring heat sinking can be any type of electronic and optical device.

In some embodiments of the present invention, the hybrid package 200 includes an active cooling system 208 that is in thermal communication with the cold-plate body 204. In the embodiment shown in FIG. 2, the active cooling system 208 is a wedge-lock type heat sink that is attached to at least a portion of the cold-plate body 204. The wedge-lock type heat sink includes cooling channels 210 that pass a coolant fluid that transfers heat away from the cold-plate body 204. One skilled in the art will appreciate that numerous other types of active cooling systems can be used to transfer heat away from the cold-plate body 204. In other embodiments, the hybrid package 200 includes an air-cooled heat sink that is in thermal communication with the cold-plate body 204. In these embodiments, the heat sink provides a significant thermal mass that draws heat from the cold-plate body 204. Fins can be attached the heat sink to assist in dissipating the heat.

The cold-plate body 204 is formed of a composite core material. In some embodiments, the composite material has a relatively low CTE skin. In other embodiments, the composite material is chosen to have a CTE that matches the CTE of the device 202 requiring heat sinking. In some embodiments, the composite material comprises discontinuous graphite fibers that are arranged in-plane. For example, the composite material can be MetGraf™ 4 or MetGraf™ 7, which is described herein and which is commercially available from Metal Matrix Cast Composites of Waltham, Mass., the assignee of the present invention.

In another embodiment, the composite core material comprises a highly-oriented pyrolytic graphite (“HOPG”) material in foil or crystalline graphite sheets. Such materials have ultra-high thermal conductivity and can be machined as described herein. Suitable HOPG cores are TPG™, which is commercially available from GE Advanced Ceramics, and SpreaderShield 30-500 material, which is commercially available from GrafTech. These materials are available in various sizes and thickness. For example, one or more sheets of the HOPG composite material can be cut to the desired size and then pre-drilled or machined to form cavities for rivets and vias that are described herein. The HOPG composite material can be pressure infiltrated with molten Al or Cu alloy material. In some embodiments, the HOPG composite material is engineered to have a CTE that approximately matches the CTE of an electronic device or ceramic package material requiring heat sinking.

In some embodiments, the region 212 below the recessed area 206 is filed with a high thermal conductivity CTE matching material. For example, in one embodiment, the region 212 below the recessed area 206 comprises Pyrograf PG-I, which is a carbon matrix material that is oriented in the Z direction. Pyrograf PG-I is commercially available from Pyrograf® Products, Inc. of Cedarville, Ohio, a subsidiary of Applied Sciences, Inc. In another embodiment, the region 212 below the recessed area 206 comprises a MetGraf™ preform that is compressed sufficiently to match the CTE of the device 202 requiring heat sinking.

In yet another embodiment, the region 212 below the recessed area 206 comprises a plurality of cavities that are filed with a relatively high conductivity material, such as a matrix alloy material. For example, the plurality of cavities can be filled with molten metal during pressure infiltration. The matrix alloy material and the density of the plurality of cavities can be chosen in order to locally CTE match the device 202 requiring heat sinking. The relatively high thermal conductivity of the matrix alloy material can also sink sufficient heat into the TPG™ high conductivity planes.

In some embodiments, a plurality of cast-in-rivets 214 is formed in the cold-plate body 204. The term “cast-in-rivet” (also called a “rivet”) is defined herein to be a cavity in the cold-plate body 204 that is filed with a material that significantly increases the structural integrity of the package 200. Cast-in-rivets can also significantly increase delamination resistance to the composite material cold-plate body 204. In addition, cast-in-rivets can facilitate heat sinking into conductive graphitic planes of the composite material cold-plate body 204 which increases the through-plane thermal conductivity of the cold-plate body 204. Furthermore, cast-in rivets can be used to improve CTE matching to the electronic device 200.

The plurality of cast-in-rivets 214 can be formed by machining or drilling cavities in the cold-plate body 204. The cavities are then filed with a material that forms the cast-in rivets 214. In some embodiments, the plurality of cast-in-rivets 214 is formed by filling the cavities with a Cu or an Al matrix alloy. In other embodiments, the plurality of cast-in-rivets 214 is formed by filling the cavities with Pyrograf PG-I, a carbon matrix material, which is available from Pyrograf® Products, Inc. of Cedarville, Ohio, a subsidiary of Applied Sciences, Inc.

In one particular embodiment, the plurality of cast-in-rivets 214 is formed by drilling or machining cavities in HOPG composite material comprising the cold-plate body 204. The HOPG composite material is cladded with appropriate MetGraf™ preforms. The MetGraf™ preforms are then pressure infiltrated with molten Al or Cu alloy material to become MetGraf™ 4 or 7 composite material (depending on the discontinuous fiber packing density). For example, the MetGraf™ preforms can be pressure infiltrated with molten Al-413 HP, which is a high purity Al—Si eutectic alloy.

The interfaces between the HOPG composite material and the preforms are under compression because the matrix alloy contracts more than the fibrous material comprising the preform during cooling from the solidification temperature. Once the liquid metal pressure infiltrated preforms solidify they become cast-in-rivets. The resulting cast-in-rivets are integrated reinforcing elements that add significant structural integrity and delamination resistance to the cold-plate body 204. In effect, the cast-in-rivets couple the HOPG core to the MetGraf™ skin, thereby causing the HOPG core material to participate in lowering the CTE of the composite material. In addition, the cast-in-rivets improve through-plane heat transfer, thereby enhancing thermal sinking.

In some embodiments, at least one cast-in-rivet via 216 is formed in the cold-plate body 204. The term “cast-in-rivet via” (also called “rivet via”) is defined herein to be a cavity in the composite material cold-plate body 204 that is filed with a material which facilitates heat sinking into the conductive graphitic planes of the composite material, thereby increasing the through-plane thermal conductivity of the composite cold-plate body 204.

In one particular embodiment of the present invention, a cast-in rivet via is formed by drilling a cavity in HOPG composite material comprising the cold-plate body 204. Commercially available HOPG material in foil or sheet form can be machined with cavities that are suitable for cast-in-rivet-vias. The cavity is then filled with a material that is suitable for providing enhanced through-plane conduction for efficient heat sinking into the HOPG composite material. For example, the cavity can be filed with a Pyrograf PG-I or a MetGraf™ preform. The preform is then pressure co-infiltrated with molten Al or Cu matrix alloy.

In some embodiments, the at least one cast-in rivet via increases the through-plane thermal conductivity of the cold-plate body 204 and also improves CTE matching of the device 202 requiring heat sinking to the composite material comprising the cold-plate body 204. In one particular embodiment, at least one cast-in-rivet via is filled with a MetGraf™ preform having a predetermined volume fraction that is chosen to have a CTE that matches the CTE of the device 202. The volume fraction of the MetGraf™ preform is adjusted by compressing it to a compression that results in the desired CTE that matches the CTE of the device 202. Also, in some embodiments, at least one of a pattern and a density of a plurality of cast-in-rivet 214 formed in the composite material cold-plate body 204 is chosen to change a local CTE of the composite material cold-plate body 204 as described herein.

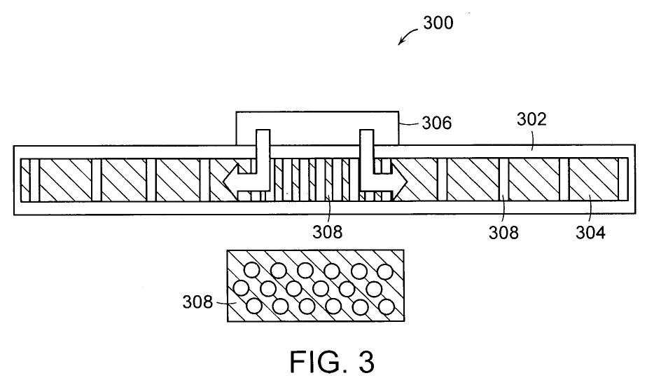

FIG. 3 illustrates a schematic view of a hybrid package 300 formed of a skin composite material 302 that encapsulates a core composite material 304. Using a separate skin and core composite material is desirable because the thermal properties of the skin and core composite materials can be independently optimized. Thus, in one embodiment, a hybrid package according to the present invention optimizes the skin composite material to CTE match a device 306 requiring heat sinking and optimizes the core composite material to spread heat generated by the device 306.

In one embodiment, the core composite material 304 is a graphitic material having a relatively high in-plane thermal conductivity and relatively low through-plane thermal conductivity. For example, the core composite material 304 can be TPG™ material, which has a 1700 W/mK in-plane thermal conductivity and a 20 W/mK through-plane thermal conductivity. One skilled in the art will appreciate that the CTE of the TPG™ core material can be engineered to be a desired CTE by properly selecting the precise volume fraction of graphitic material through calibration data.

An encapsulating skin 302 is formed when the graphitic preform is pressure infiltrated with molten Cu or Al (depending on the alloy system chosen) and then solidified. It is desirable have a skin encapsulant that prevents exposure of the core composite material 304 to the surface of the hybrid package 300. In one embodiment, the skin composite material 302 is a graphitic preform, such as a MetGraf™ preform that clads the core composite material 304 and the rivets 308 as described herein. The CTE of the encapsulating skin 302 can be chosen to approximately match the CTE of the device 306. The encapsulating skin 302 provides an electroplating surface suitable for attaching a device requiring heat sinking, such as a semiconductor package, using soldering or an adhesive material.

In one embodiment, the mismatch strain between the core composite material 304 and the encapsulating skin 302 is minimized by using an encapsulating skin 302 comprising a relatively low CTE formulation of the Al or Cu MetGraf™ composite material, such as MetGraf™ 4 composite material. MetGraf™ 4 composite material is also desirable because it is relatively durable and has an in-plane CTE that is relatively close to the in-plane CTE of TPG™ core composite material. Consequently, MetGraf™ 4 has a lower CTE mismatch strain at the MetGraf™ skin/HOPG core interface.

In one embodiment, the hybrid package 300 includes a plurality of cast-in-rivets 308. The plurality of cast-in-rivets 308 can be formed in numerous ways as described herein. For example, a plurality of cavities can be drilled or machined in the core composite material 304. Each of the plurality of cavities is cladded with a preform, such as a MetGraf™ preform. The preforms are then pressure infiltrated with molten Cu or Al alloy (depending on the alloy system chosen) and then solidified to form the plurality of cast-in-rivets 308.

The resulting plurality of cast-in-rivets 308 forms a plurality of integrated reinforcing elements that add significant structural integrity and delamination resistance to the hybrid package 300 as described herein. In addition, the plurality of cast-in-rivets 308 improves through-plane heat transfer that sinks heat from the device 306 to the in-plane high thermal conductivity of the core composite material 304 where the heat is spread to the periphery of the hybrid package 300. The heat at the periphery of the hybrid package 300 can be removed by an active cooling system or by a larger heat sink as described in connection with FIG. 2.

In one embodiment of the present invention, the density of the plurality of cast-in-rivets 308 in the region under the device 306 is chosen to achieve a local CTE that matches the CTE of the device 306. Shapery's equation can be used to estimate the CTE of the core composite material with an increased density of cast-in-rivets. Calculations using Shapery's equation will result in relatively accurate results for TPG™ material because of the material's high intrinsic stiffness that approaches 150 msi and the material's negative CTE that is about 1 ppm.

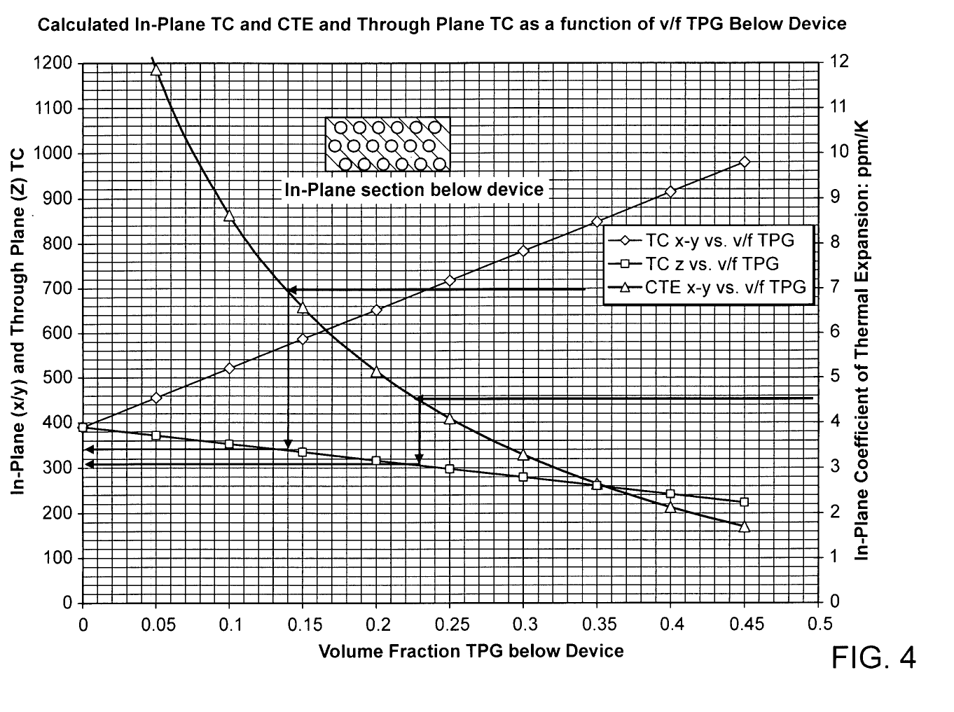

FIG. 4 illustrates a plot 400 of calculated in-plane thermal conductivity (TC), through-plane thermal conductivity (TC), and CTE as a function of volume fraction of TPG™. The plot 400 indicates that to achieve a CTE equal to about 4.5 ppm/K, which is required to match a SiC or GaN semiconductor package, the local volume fraction of TPG™ material should be about 0.23. The plot 400 also indicates that to achieve a CTE equal to about 7 ppm/K, which is needed to match an alumina or a GaAs package, the local volume fraction of TPG™ material should be about 0.14. One skilled in the art will appreciate that more accurate data for local volume fractions can be determined experimentally.

The corresponding through-plane thermal conductivity (TC) was calculated using modulus modified rule of mixtures calculations for thermal expansion based on a Cu matrix having a thermal conductivity that is equal to 390 W/mK. The through-plane thermal conductivity (TC) was determined to be about 300 W/mK for a CTE of that is equal to about 4.5 ppm/K. The through-plane thermal conductivity (TC) was determined to be about 340 W/mK for a CTE that is equal to about 7 ppm/K. In one embodiment of the present invention, the thermal conductivity and the CTE of a package according to the present invention is optimized using Shapery's equation to calculate CTE and rule of mixtures calculations to determine the through-plane thermal conductivity (TC) and in-plane thermal conductivity (TC).

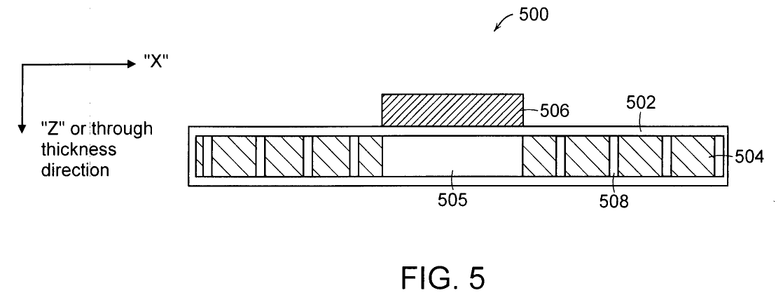

FIG. 5 illustrates a schematic view of another embodiment of a hybrid package 500 formed of a skin composite material 502 that encapsulates a core composite material 504 that includes a CTE matching composite material insert 505 positioned beneath the device 506 requiring heat sinking. In one embodiment, the hybrid package 500 optimizes the skin composite material so that it CTE matches the device 506 and optimizes the core composite material 504 to spread heat generated by the device 506.

In one embodiment, the core composite material 504 is a graphitic material having a relatively high in-plane thermal conductivity and a relatively low through-plane thermal conductivity, such as TPG™ material. An encapsulating skin 502 is formed when the graphitic preform is pressure infiltrated with molten Cu or Al (depending on the alloy system chosen) and then solidified. The encapsulating skin 502 provides an electroplating surface suitable for attaching a device requiring heat sinking, such as a semiconductor package, using soldering or an adhesive material.

In one embodiment, the skin composite material 502 is a graphitic preform, such as a MetGraf™ preform, that clads the core composite material 504 and the rivets 508 as described herein. For example, the skin composite material 502 can be a relatively low CTE formulation of Al or Cu MetGraf™ composite material, such as MetGraf™ 4 composite material, as described herein. The CTE of the encapsulating skin 502 can be chosen to approximately match the CTE of the device 506.

In one embodiment, the hybrid package 500 includes a plurality of cast-in-rivets 508. The plurality of cast-in-rivets 508 can be formed in numerous ways as described herein. For example, a plurality of cavities can be drilled or machined in the core composite material 504. Each of the plurality of cavities is cladded with a preform, such as a MetGraf™ preform. The preforms are then pressure infiltrated with molten Cu or Al (depending on the alloy system chosen) and then solidified to form the plurality of cast-in-rivets 508.

The resulting plurality of cast-in-rivets 508 form a plurality of integrated reinforcing elements that add significant structural integrity and delamination resistance to the hybrid package 500 as described herein. In addition, the plurality of cast-in-rivets 508 improves through-plane heat transfer that sinks heat from the device 506 to the in-plane high thermal conductivity of the core composite material 504 where the heat is spread to the periphery of the hybrid package 500. The heat at the periphery of the hybrid package 500 can be removed by an active cooling system or by a air-cooling heat sink as described in connection with FIG. 2.

The hybrid package 500 includes a CTE matching composite material insert 505 positioned beneath the device 506 that provides more precise local CTE matching proximate to the device 506. In one embodiment, the insert 505 is formed by machining a via under the device 506 and then inserting a graphitic preform, such as a MetGraf™ preform into the via. The perform is then infiltrated with molten Cu or Al (depending on the alloy system chosen) and then solidified to form the insert 505.

For example, a MetGraf™ 7 insert infiltrated with Cu can be formed with a CTE equal to about 7 ppm/K. The in-plane thermal conductivity of such an insert has been measured to be about 300 W/mK and the through-plane thermal conductivity has been measured to be 230 W/mK. Also, a MetGraf™ 4 insert infiltrated with Cu can be formed with a CTE that is equal to about 4 ppm/K. The in-plane thermal conductivity of such an insert has been measured to be about 290 W/mK and the through-plane thermal conductivity has been measured to be about 190 W/mK. The hybrid package including the MetGraf™ 7 or the MetGraf™ 4 insert has significantly higher heat sinking capability than hybrid packages with TPG™ core material beneath the device 506, which have a thermal conductivity of about 20 W/mK.

One skilled in the art will appreciate that there are many other possible types of insert materials. For example, the insert material can be sintered Mo that when infiltrated with Al or Cu provides a CTE match to the device 506. The insert material can also be Pyrograf 1, a vapor grown graphite fiber product commercially available from Advanced Materials of Xenia, Ohio that has a high axial thermal conductivity. The insert material can also be Uniaxial K-1100 graphite fiber, which has approximately a 900 W/mK thermal conductivity along the fiber axis. In addition, the insert material can be posts of TPG™ oriented in the “Z” direction within a via.

Hybrid packages according to the present invention can be engineered to control the CTE in one elongated direction. This feature is important for some elongated semiconductor devices. In one embodiment, the MetGraf™ preform inert is oriented to provide high thermal conductivity in the through-plane direction while maintaining the ability to CTE match in the elongated direction of the device. For example, a MetGraf™ preform insert infiltrated with Cu has a thermal conductivity that is equal to about 300 W/mK properly oriented in the elongated direction and can provide CTE matching to many devices.

An exemplary process for manufacturing a hybrid package according the present invention is now described. One skilled in the art will appreciate that there are numerous variations of this process and numerous other processes for fabricating the hybrid package described herein. The manufacturing begins with by forming the cold-plate body 204 from DKD or DKAx milled graphite fibers with an average length of 200-300 microns. DKAx milled graphite fibers are commercially available from Cytec Industries Inc. of West Paterson, N.J. These fibers are spray deposited, as described in U.S. patent application Ser. No. 11/163,486, with an aqueous PEG 8000 binder into sheet preforms. The sheet preforms are then compressed to a 35% volume fraction. The resulting pressed block of material has a CTE of about 4 ppm/K when pressure infiltrated with Al.

A plurality of 0.120″ deep cavities are machined in the resulting pressed block to receive three 0.040″ thick TPG™ inserts. The inserts are placed in the cavities and the pressed block is then covered with a slab of compressed MetGraf™ preform. A plurality of cavities is drilled through the TPG™ inserts forming a plurality of small cavities and a larger void. The TPG™ inserts can be pre drilled with apertures forming cavities for rivets. TPG™ slabs with dimensions of about 0.06″ by 2.92 by 0.04″ thick are then loaded into the void that was machined from the preform block and covered with a 0.04″ thick slab of the same DKAX preform.

The preform block is placed into graphite cavities in mold vessels and pressure infiltrated with Al-413HP alloy or with Cu-0.6 Cr alloy as described in U.S. Pat. No. 6,148,899. The cavities and the void are filled with molten matrix alloy during pressure infiltration. The matrix material that solidifies in the cavities forms a plurality of cast-in rivets 214 and the cast-in rivet-via 216.

In embodiments that include Al matrix alloy material, the solidified Al matrix alloy has a higher CTE than the TPG™ insert in the “Z” direction. Consequently, during cooling from the solidification temperature, the hybrid package is placed under tension. The tension results in strong contact between the matrix alloy material and the TPG™ insert which improves resistance to delamination. The resulting cast-in rivets and rivet-vias also serve to make the package more structurally robust.

Numerous hybrid packages have been made by infiltrating Cu and Al matrix materials. Many hybrid packages have been made with 0.04″ cast-in-rivets and 0.5″ cast-in rivet vias filled with various materials, such as Pyrograf PG-I in “Z” direction, MetGraf™ 7 preforms in “X-Y” direction, DKAx ribbon in “Z” direction, and with AI 356 slugs.

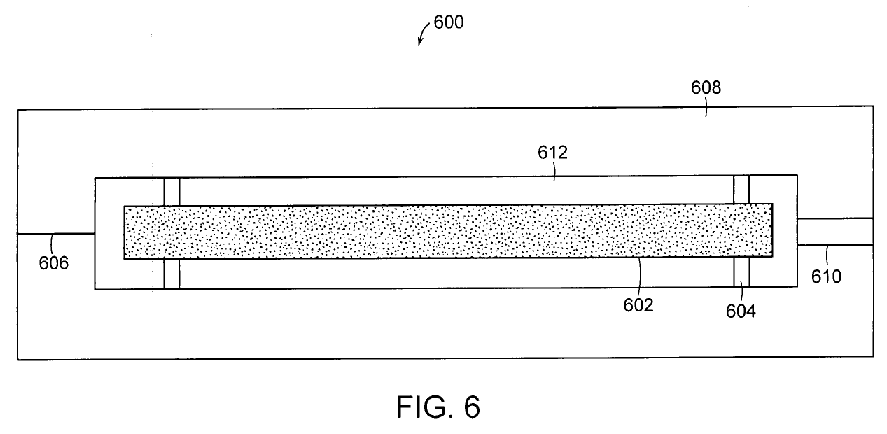

FIG. 6 shows a schematic diagram of a partially fabricated hybrid package 600 during pressure infiltration that illustrates a method of positioning a core composite material 602 in a hybrid package 600 according to the present invention. It is desirable for the core composite material 602 to be placed along the centerline 606 of the hybrid package 600 to prevent warping. It is also desirable to machine surfaces of the hybrid package 600 while maintaining the core composite material 602 securely positioned along the centerline.

In one embodiment, a hybrid package 600 is manufactured by fixing the core composite material 602 in place. According to one aspect of the present invention, stand-off positioning pins 604 are used to fix the core composite material 602 along the center line 606 of the casting as illustrated in FIG. 6. For example, TPG™ core material 602 can be positioned in a mold 608 using Molybdenum (Mo) pins 604. Molybdenum is a good choice for a pin material used with Cu matrix composites because Mo is easily wet by Cu and because Mo forms a good bond. In addition, Mo is a good choice for a pin material because it does not contaminate the matrix alloy and, consequently, does not decrease thermal conductivity. Molybdenum, Titanium, and steel are good choices for pin materials used for Al matrix composites.

The pins 604 are in contact with the surface of the mold 608 and the composite material core 604. The composite material core 604 can be adequately centered in the mold 608 after pressure infiltration by properly selecting the dimension of the pins 604. Liquid metal, such as Cu or Al, is introduced under pressure through a gate 610 and allowed to pressure infiltrate the MetGraf™ or other graphite preform to provide the Cu (or Al) MetGraf™ or other composite material skin 612. The composite material core 602 is maintained in a center position within the mold 608 during pressure infiltration. The pins 604 are permitted to penetrate into the MetGraf™ or other graphite preform, which becomes a Cu or Al composite material skin 612 after pressure infiltration.

The resulting composite material core 602 is encapsulated and properly positioned for subsequent machining to prepare the proper package dimensions and surface finish. The pins 604 may be visible from the surface of the mold 608, but since they are well bonded with the matrix material, they can be co-machined without consequence. After removal of the hybrid package 600 from the mold 608, it is necessary to machine the casting surfaces so that the hybrid package 600 has to the desired dimensions.

It is desirable to provide a means for indicating the position of the composite material core 602 during surface material removal. One means for indicating the position of the composite material core 602 is to insert a sacrificial material, such as solid graphite, into the mold 608. The insert of sacrificial material can have a notch machined into it which has the same dimensions as the composite material core 602 and which is located so as to define and index the location of the top and bottom of the composite material core 602.

A machinist can then mill away the end of the casting so as to reveal a notch. The top and bottom of the plate can then be milled until the proper thickness is achieved, taking care to leave the composite core material centered within the machined hybrid package. The graphite insert material can then be milled away because it is no longer needed to index the location of the top and bottom surface of the composite material core 602.

One skilled in the art will appreciate that there are many other ways of positioning the core 602 within a composite material preform and indexing the amount of surface to be milled to provide the desired skin thickness. For example, the metal matrix casting can be formed into conical sections. By measuring the diameter of the circular pin regions revealed after a machining pass, one can calculate the amount remaining to be machined if one knows the dihedral angle of the cone.

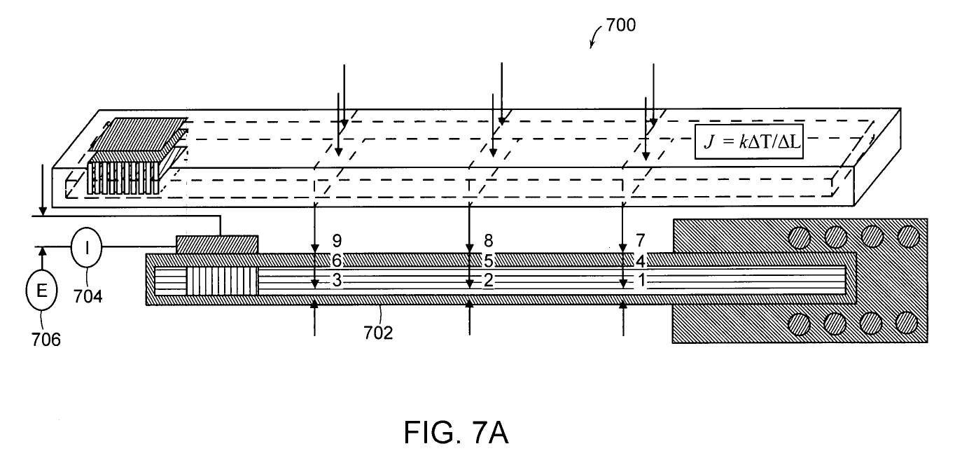

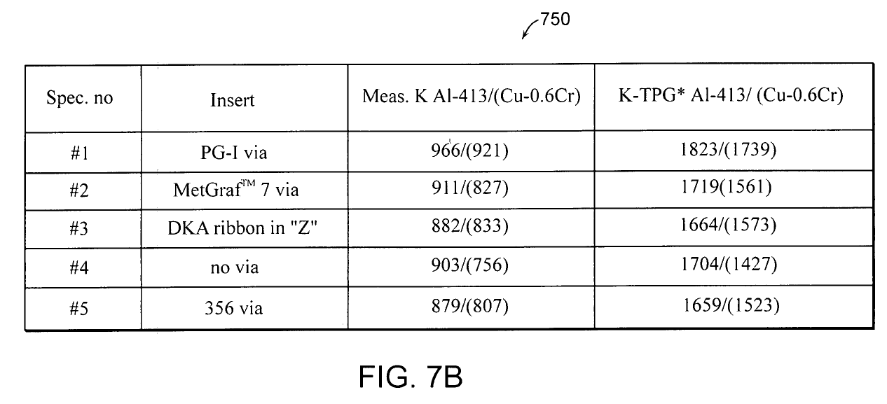

FIG. 7A is a schematic diagram 700 illustrating the measurement of steady state thermal conductivity of a hybrid package 702 fabricated according to the present invention. The arrows indicate the measurement points used to determine temperature gradients. An ammeter 704 and a voltmeter 706 are used to determine the power applied to the hybrid package 702, which can be used to determine the applied heat flux.

FIG. 7B presents a table 750 of data for thermal flux conducted through the hybrid package 702. The thermal flux being conducted through the hybrid package 702 was determined by subtracting calculated values for temperature dependent conduction losses for pure copper from the applied heat flux. The applied heat flux was calculated from the current and voltage measurements taken from the ammeter 704 from the voltmeter 706.

The data assumes that the hybrid package has a skin comprising either MetGraf™ 4 pressure infiltrated with Al matrix material that has a thermal conductivity of about 200 W/mK or a skin comprising MetGraf™ 4 pressure infiltrated with Cu matrix material that has a thermal conductivity of about 237 W/mK. The data also assumes that the thermal conductivity of the TPG™ insert is about 1,716 W/mK for infiltration with Al matrix materials and 1,564 W/mK for infiltration with Cu matrix material.

Data is presented for five different types of cast-in-rivet vias and for two different types of cast-in-rivets. The five different types via-insert materials include Pyrograf PG-I material, MetGraf™ 7 material, DKA ribbon in “Z” material, 356 Al material and no cast-in-rivet via (which is no via at all). Data for the two different types of cast-in-rivet materials is presented for both pressure infiltrated Al and Cu matrix materials. The data for the first cast-in-rivet is for Al 356 for the Al casting and Cu-0.5 Cr for the Cu casting. The data for the second cast-in-rivet is for a TPG™ cast-in-rivet that is pressure infiltrated with Al-413 and with Cu-0.6Cr matrix material.

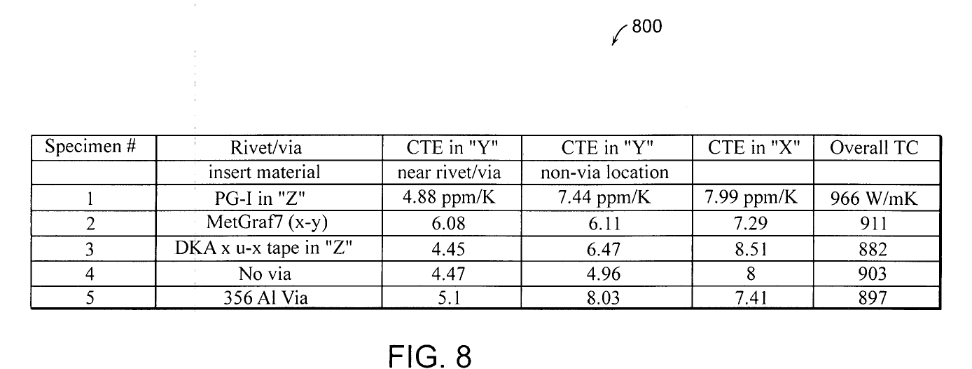

FIG. 8 presents a table 800 of CTE data and overall thermal conductivity data for five different cast-in-rivet via materials. The five different types of cast-in-rivet via materials include Pyrograf PG-I material, MetGraf 7 material, DKA ribbon in “Z” material, Al 356 material and no cast-in-rivet via. CTE data is presented for both “Y” direction CTE and for “X” direction CTE. During experiments it was determined that there was substantially no warping or delamination during thermal cycling and acquiring CTE data.

The data presented in the table 800 of FIG. 8 shows that the CTE in the “Y” direction is in the range of 4.45 to 6 ppm/K depending upon the type of insert material. Data is presented for CTE in the “Y” direction in regions proximate to the cast-in-rivets and to the cast-in-rivet vias and also in regions away from the cast-in-rivets and the cast-in rivet vias. The data presented in table 800 of FIG. 8 also shows that the CTE in the “X” direction is in a narrower range of 7.29 to 8.51 ppm/K.

These data indicate that by properly selecting the insert material, the CTE of a hybrid package according to the present invention can be precisely matched to a device requiring heat sinking. CTE matching to devices requiring heat sinking was demonstrated for a CTE equal to about 7 ppm/K and for a CTE equal to about 4 ppm/K. In addition, these data indicate that cast-in-rivet vias comprising Pyrograf PG-I graphite material have relatively low CTE and relatively high overall thermal conductivity. These data also indicate that MetGraf™ 7, which is currently much less expensive than Pyrograf PG-I, also has relatively low CTE and relatively high overall thermal conductivity. In general, Al matrix hybrids had slightly better properties than Cu matrix hybrids with same hybrid architecture.

### EQUIVALENTS

While the present teachings are described in conjunction with various embodiments and examples, it is not intended that the present teachings be limited to such embodiments. On the contrary, the present teachings encompass various alternatives, modifications and equivalents, as will be appreciated by those of skill in the art, may be made therein without departing from the spirit and scope of the invention as defined by the appended claims.

What is claimed is:

1. A hybrid package for heat sinking a device, the hybrid package being formed of a graphitic material that defines a plurality of cavities for cast-in-rivets and that defines at least one cavity for a cast-in-rivet via, the graphitic material being pressure infiltrated with a molten metal alloy so as to form a composite material with a plurality of cast-in rivets that increases at least one of a through-plane conductivity and a strength of the hybrid package and that forms at least one cast-in-rivet that increases an in-plane thermal conductivity of the hybrid package.

2. The hybrid package of claim 1 wherein the graphitic material comprises discontinuous graphite fibers randomly distributed in-plane.

3. The hybrid package of claim 1 wherein the graphitic material has a relatively high in-plane thermal conductivity and relatively low through-plane thermal conductivity.

4. The hybrid package of claim 1 wherein the graphitic material comprises a highly-oriented pyrolytic graphite material.

5. The hybrid package of claim 1 wherein the metal alloy comprises at least one of Al and Cu.

6. The hybrid package of claim 1 wherein a CTE of the composite material approximately matches a CTE of the device.

7. The hybrid package of claim 1 wherein at least one of a pattern and a density of the cast-in-rivets is chosen to increase a resistance to delamination.

8. The hybrid package of claim 1 wherein at least some of the plurality of cast-in-rivets are formed in a region under the device.

9. The hybrid package of claim 8 wherein at least one of a pattern and a density of the plurality of cast-in-rivets in the region under the device is chosen to achieve a local CTE proximate to the device that approximately matches the CTE of the device.

10. The hybrid package of claim 1 further comprising a recessed area formed in the composite material suitable for mounting the device.

11. The hybrid package of claim 1 further comprising an insert that is positioned under the device.

12. The hybrid package of claim 11 wherein a CTE of the insert approximately matches a CTE of device.

13. The hybrid package of claim 11 wherein the insert has a through-plane thermal conductivity that is higher than a through-plane thermal conductivity of the composite material forming the hybrid package.

14. The hybrid package of claim 11 wherein the insert is formed of a carbon matrix material that is oriented in the Z direction.

15. The hybrid package of claim 1 further comprising a cooling system in thermal contact with the hybrid package that removes heat from the hybrid package with at least one of a cooling fluid and air cooling fins.

16. A hybrid package for heat sinking a device, the hybrid package comprising:
a core composite material that defines a plurality of cavities for cast-in-rivets, each of the plurality of cavities being cladded with a graphitic preform; and
a skin composite material that is formed by pressure infiltrating a graphitic preform with a molten alloy, the pressure infiltration forming a metal matrix skin composite material that clads the core composite material, and forming a plurality of cast-in-rivets in the plurality of cavities, wherein the plurality of cast-in-rivets increases a through-plane thermal conductivity and increases a strength of the hybrid package.

17. The hybrid package of claim 16 wherein the core composite material comprises a composite material having a relatively high through-plane thermal conductivity that spreads heat generated by the device.

18. The hybrid package of claim 16 wherein the core composite material comprises a highly-oriented pyrolytic graphite composite material.

19. The hybrid package of claim 16 wherein the skin composite material completely encapsulates the core composite material after infiltration with the molten alloy.

20. The hybrid package of claim 16 wherein a CTE of the skin composite material is chosen to approximately match a CTE of the device.

21. The hybrid package of claim 16 wherein the alloy material comprises at least one of Al or Cu.

22. The hybrid package of claim 16 wherein at least some of the plurality of cast-in-rivet are filled with a graphitic preform having a predetermined volume fraction that is chosen to result in a predetermined CTE after pressure infiltration.

23. The hybrid package of claim 16 wherein at least one of the core composite material and the skin composite material has a volume fraction that is chosen to reduce strain at an interface between the core composite material and the skin composite material.

24. The hybrid package of claim 16 wherein at least one of a pattern and a density of the plurality of cast-in-rivets in a region under the device is chosen to achieve a local CTE proximate to the device that approximately matches the CTE of the device.

25. The hybrid package of claim 16 wherein at least one of a pattern and a density of the plurality of cast-in-rivets is chosen to increase a resistance to delamination.

26. A hybrid package for heat sinking a device, the hybrid package comprising:
a core composite material that defines a plurality cavities for cast-in-rivets, each of the plurality of cavities being cladded with a graphitic preform;
an insert that is embedded into the core composite material in a region below the device; and
a skin composite material that is formed by pressure infiltrating a graphitic preform with a molten alloy, the pressure infiltration forming a metal matrix skin composite material that clads the core composite material and the insert, and forming a plurality of cast-in-rivets in the plurality of cavities, wherein the plurality of cast-in-rivets increases a through-plane conductivity and increases a strength of the hybrid package.

27. The hybrid package of claim 26 wherein the insert comprises a graphitic preform that is pressure infiltrated with the molten alloy.

28. The hybrid package of claim 27 wherein a volume fraction of the graphitic preform comprising the insert is chosen to result in an insert having a predetermined CTE.

29. The hybrid package of claim 27 wherein the insert has a CTE after pressure infiltration that approximately matches a CTE of the device.

30. The hybrid package of claim 26 wherein the skin composite material completely encapsulates the core composite material and the insert after pressure infiltration with the molten alloy.
